(19) United States
(12) Patent Application Publication
(10) Pub. No.: US 2009/0146304 A1
(43) Pub. Date: Jun. 11, 2009

(54) CARBON NANOTUBE INTEGRATED CIRCUIT DEVICES AND METHODS OF FABRICATION THEREFOR USING PROTECTED CATALYST LAYERS

(75) Inventors: Yoon-ho Son, Gyeonggi-do (KR); Sun-woo Lee, Incheon (KR); Young-moon Choi, Seoul (KR); Seong-ho Moon, Gyeonggi-do (KR); Hong-sik Yoon, Gyeonggi-do (KR); Suk-hun Choi, Gyeonggi-do (KR); Kyung-rae Byun, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/924,308

(22) Filed: Oct. 25, 2007

(30) Foreign Application Priority Data
Oct. 26, 2006 (KR) 2006-104545
Dec. 6, 2006 (KR) 2006-123086

(51) Int. Cl. H01L 23/522; H01L 21/768

(52) U.S. Cl. 257/750; 438/652; 257/E23.145; 257/E21.585

(57) ABSTRACT

A method of fabricating an integrated circuit device is provided. The method includes sequentially forming a lower interconnection layer, a catalyst layer, and a buffer layer on a semiconductor substrate, forming an interlayer dielectric layer to cover the buffer layer, forming a contact hole through the interlayer dielectric layer so that a top surface of the buffer layer may be partially exposed, removing a portion of the buffer layer exposed by the contact hole so that a top surface of the catalyst layer may be exposed, and growing carbon nanotubes from a portion of the catalyst layer exposed by the contact hole so that the contact hole may be filled with the carbon nanotubes.

### RELATED APPLICATION

This application claims priority from Korean Patent Application No. 10-2006-0104545 filed on Oct. 26, 2006 and Korean Patent Application No. 10-2006-0123086 filed on Dec. 6, 2006 in the Korean Intellectual Property Office, the disclosure of each of which is incorporated herein by reference in its entirety.

### BACKGROUND OF THE INVENTION

The present invention relates to integrated circuit devices and methods of fabrication therefor and, more particularly, to carbon nanotube devices and methods of fabrication therefor.

The ever-growing demand for highly integrated semiconductor devices has resulted in a considerable reduction in the design rule of semiconductor devices and an increase in the operating speed of semiconductor devices. Accordingly, the line width of interconnections has decreased, and the current density of interconnection has increased. Thus, interconnection materials having improved properties are increasingly desirable.

Carbon nanotubes may provide high electrical conductivity and excellent gap-fill characteristics and, therefore, may be appropriate for use in the fabrication of interconnections and contacts of highly integrated devices. Conventionally, in order to form interconnections and contacts utilizing carbon nanotubes, a catalyst layer may be formed and carbon nanotubes grown from the catalyst layer.

The catalyst layer may include a thin transition metal layer formed on an underlying interconnection layer. The catalyst layer may be easily damaged during etching processes used in manufacture of integrated circuit devices. When the catalyst layer is damaged, carbon nanotubes may not be properly grown, which may degrade properties of the integrated circuit device.

Transition metals used to form a catalyst layer may exhibit poor adhesiveness to oxide layers. For example, an oxide interlayer dielectric layer directly formed on a catalyst layer formed of such a transition metal may be easily detached from the underlying layers due to poor adhesiveness between the oxide layer and the catalyst layer. This may cause an increase in defect rate.

### SUMMARY OF THE INVENTION

Some embodiments of the present invention provide methods of fabricating integrated circuit devices. A stack is formed including an interconnection layer on a substrate, a catalyst layer on the interconnection layer and a buffer layer on the catalyst layer. An interlayer dielectric layer is formed on the buffer layer. A hole is formed through the interlayer dielectric layer to expose a portion of the buffer layer. The exposed portion of the buffer layer is removed to expose a portion of the catalyst layer. Carbon nanotubes are grown on the exposed portion of the catalyst layer. Forming the hole through the interlayer dielectric layer may include performing a first etching process using the buffer layer as an etching stopper and removing the exposed portion of the buffer layer to expose the portion of the catalyst layer may include performing a second etching process. The first and second etching processes may have different etching selectivities. For example, the first etching process may include a dry etching process and the second etching process may include a wet etching processes. In some embodiments, the first and second etching processes may include respective different dry etching processes.

In some embodiments, forming a stack including an interconnection layer on a substrate, a catalyst layer on the interconnection layer and a buffer layer on the catalyst layer may include depositing a conductive material layer on the substrate, depositing a catalyst material layer on the conductive layer, depositing a buffer material layer on the catalyst material layer and patterning the buffer material layer, the catalyst material layer and the conductive material layer to form the stack. In further embodiments, forming a stack including an interconnection layer on a substrate, a catalyst layer on the interconnection layer and a buffer layer on the catalyst layer may include depositing a conductive material layer on the substrate, depositing a catalyst material layer on the conductive layer, and patterning the conductive material layer and the catalyst material layer to form a catalyst pattern on a conductive pattern. A buffer material layer may be deposited to conform to a top surface of the catalyst pattern and sidewalls of the catalyst pattern and the conductive pattern. The buffer material layer may be patterned to expose a portion of the substrate adjacent the sidewalls of the catalyst pattern and the conductive pattern.

In still further embodiments, forming a stack including an interconnection layer on a substrate, a catalyst layer on the interconnection layer and a buffer layer on the catalyst layer may include forming a damascene conductive layer in a dielectric layer on the substrate, depositing a catalyst material layer on the damascene conductive layer, depositing a buffer material layer on the catalyst material layer and patterning the buffer material layer and the catalyst material layer to leave a catalyst layer and a buffer layer on the damascene conductive layer.

In further embodiments of the present invention, an integrated circuit device may include a substrate and a stack of layers including an interconnection layer on the substrate, a catalyst layer on the interconnection layer and a buffer layer on the catalyst layer. An interlayer dielectric layer may be disposed on the buffer layer, and a carbon nanotube contact may extend through the interlayer dielectric layer and the buffer layer to contact the catalyst layer.

Some embodiments of the present invention may provide methods of fabricating an integrated circuit device having improved properties.

Some embodiments of the present invention may also provide integrated circuit devices having improved properties.

According to some aspects of the present invention, there is provided a method of fabricating an integrated circuit device. The method includes sequentially forming a lower interconnection layer, a catalyst layer, and a buffer layer on a semiconductor substrate, forming an interlayer dielectric layer to cover the buffer layer, forming a contact hole through the interlayer dielectric layer so that a top surface of the buffer layer may be partially exposed, removing a portion of the buffer layer exposed by the contact hole so that a top surface of the catalyst layer may be exposed, and growing carbon nanotubes from a portion of the catalyst layer exposed by the contact hole so that the contact hole may be filled with the carbon nanotubes.

According to other aspects of the present invention, there is provided a method of fabricating an integrated circuit device. The method includes forming a first interlayer dielectric layer having a recess on a semiconductor substrate, forming a damascene interconnection layer by the recess may be filled with a conductive layer, forming a conductive layer for forming a catalyst layer and a thin film for forming a buffer layer on the damascene interconnection layer and on the first interlayer dielectric layer, forming a catalyst layer and a buffer layer on the damascene interconnection layer by patterning the thin film and the conductive layer, forming a second interlayer dielectric layer on the first interlayer dielectric layer and on the buffer layer, forming a contact hole through the second interlayer dielectric layer so that a top surface of the buffer layer may be exposed, removing a portion of the buffer layer exposed by the contact hole so that a top surface of the catalyst layer may be exposed and growing carbon nanotubes from a portion of the catalyst layer exposed by the contact hole so that the contact hole may be filled with the carbon nanotubes.

According to other aspects of the present invention, there is provided an integrated circuit device. The integrated circuit device includes a lower interconnection layer which is formed on a semiconductor substrate, a catalyst layer which is formed on the lower interconnection layer, a buffer layer which is formed on the catalyst layer and partially exposes the catalyst layer, an interlayer dielectric layer which is formed on the buffer layer, a contact hole which is formed through the interlayer dielectric layer and exposes a portion of the catalyst layer exposed by the buffer layer, and carbon nanotubes which are grown from the exposed portion of the catalyst layer and fill the contact hole.

### BRIEF DESCRIPTION OF THE DRAWINGS

FIG. 1 is a flowchart illustrating operations for fabricating integrated circuit devices according to some embodiments of the present invention;

FIGS. 2A through 7B are plan and cross-sectional views illustrating operations of FIG. 1;

FIG. 8 is a flowchart illustrating operations for fabricating integrated circuit devices according to some embodiments of the present invention;

FIGS. 9A through 16B are plan and cross-sectional views illustrating operations of FIG. 8;

FIG. 17 is a flowchart illustrating operations for fabricating integrated circuit devices according to some embodiments of the present invention;

FIGS. 18A through 25B are plan and cross-sectional views illustrating operations of FIG. 17;

FIG. 26 is a flowchart illustrating operations for fabricating integrated circuit devices according to some embodiments of the present invention; and

FIGS. 27A through 33B are plan and cross-sectional views illustrating operations of FIG. 26.

### DETAILED DESCRIPTION OF THE INVENTION

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present. As used herein, the term “and/or” includes any and all combinations of one or more of the associated listed items.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly. As used herein, “height” refers to a direction that is generally orthogonal to the faces of a substrate.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “comprise,” “comprising,” “includes,” “including,” “have”, “having” and variants thereof specify the presence of stated features, integers, steps, operations, elements, and/or components, but do not preclude the presence and/or addition of one or more other features, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention. Like reference numerals refer to like elements throughout.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

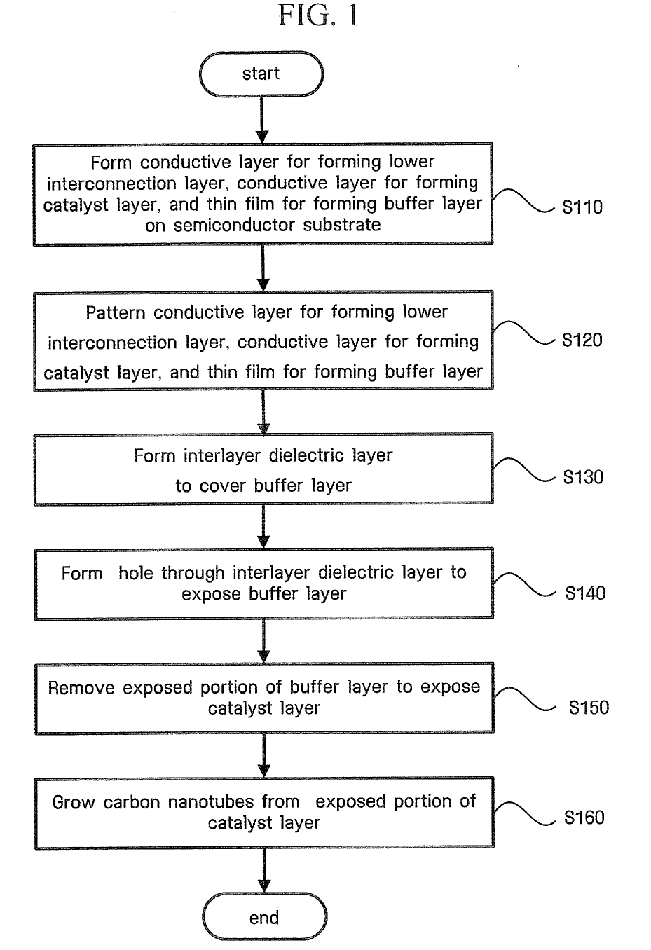

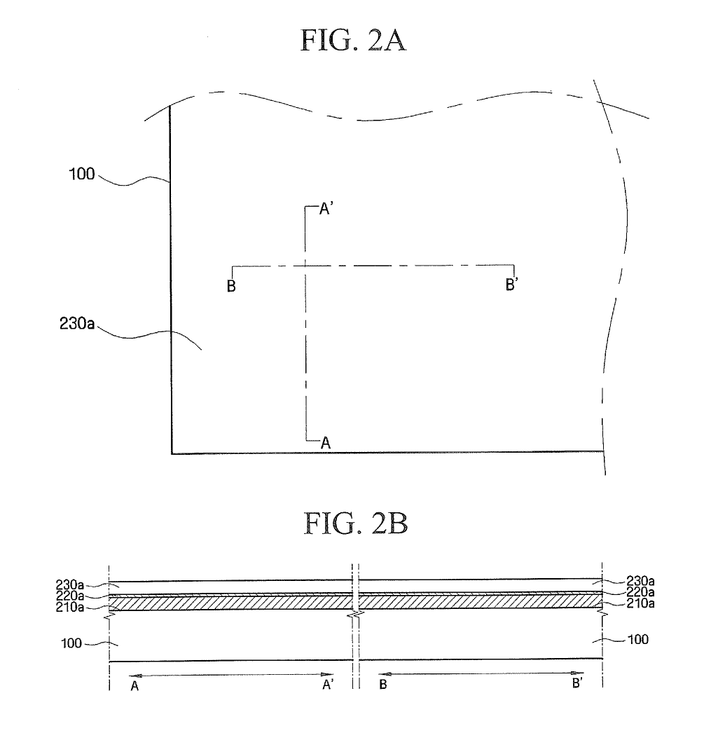

Methods of fabricating an integrated circuit device according to first embodiments of the present invention will hereinafter be described in detail with reference to FIGS. 1 through 7B. FIG. 1 is a flowchart illustrating operations for fabricating an integrated circuit device according to some embodiments of the present invention, and FIGS. 2A through 7B are plan and cross-sectional views illustrating operations from FIG. 1.

Referring to FIGS. 1 through 2B, in block S110, a conductive layer 210a for forming lower interconnections, a conductive layer 220a for forming a catalyst layer, and a thin film 230a for forming a buffer layer are formed on a semiconductor substrate 100. The semiconductor substrate 100 may include a silicon substrate, a silicon-on-insulator (SOI) substrate, a gallium asbestos (GaAs) substrate, a silicon germanium (SiGe) substrate, a ceramic substrate, a quartz substrate, and a glass substrate for a display device. The semiconductor substrate 100 may be a P-type substrate. The semiconductor substrate 100 may be a P-type semiconductor substrate and may be a double layer consisting of a P-type semiconductor substrate and a P-type epitaxial layer (not shown) that is grown from the P-type semiconductor substrate.

Metal interconnections may be formed under the conductive layer 210a. Transistors may be formed under the conductive layer 210 and may be connected to the conductive layer 210 via contacts.

The conductive layer 210a for forming lower interconnections may be formed using, for example, a chemical vapor deposition (CVD) method or a physical vapor deposition (PVD) method. The conductive layer 210a may be formed of a metal and/or other conductive materials. For example, the conductive layer 210a may be formed of a metal such as W, Al, TiN, Ti, or a combination thereof. The conductive layer 210a may be formed to a thickness of about 100-1000 Å.

The conductive layer 220a for forming a catalyst layer may be used as a catalyst layer during a subsequent process for growing carbon nano-tubes. The conductive layer 220a may be formed using, for example, a magnetron sputtering device or an electron beam evaporator. The conductive layer 220a may be formed by applying transition metal powders onto the conductive layer 210a, but the present invention is not restricted thereto. The conductive layer 220a may be formed of, for example, Ni, Fe, Co, Au, Pb, or a combination thereof. The conductive layer 220a may be formed to a thickness of about 10-80 Å.

The thin film 230a for forming a buffer layer may be formed using, for example, a CVD method or a PVD method. The thin film 230a may be formed to a thickness of about 100-1000 Å. The thin film 230a may be formed of a material having excellent adhesiveness to an interlayer dielectric layer that will be formed in a subsequent operation. The thin film 230a may be formed of the same material as the conductive layer 210a.

The thin film 230a may be formed of a conductive material. For example, the thin film 230a may be formed of W, Al, TiN, Ti, or a combination thereof. In some embodiments, the thin film 230a may include a dielectric layer, such as a nitride.

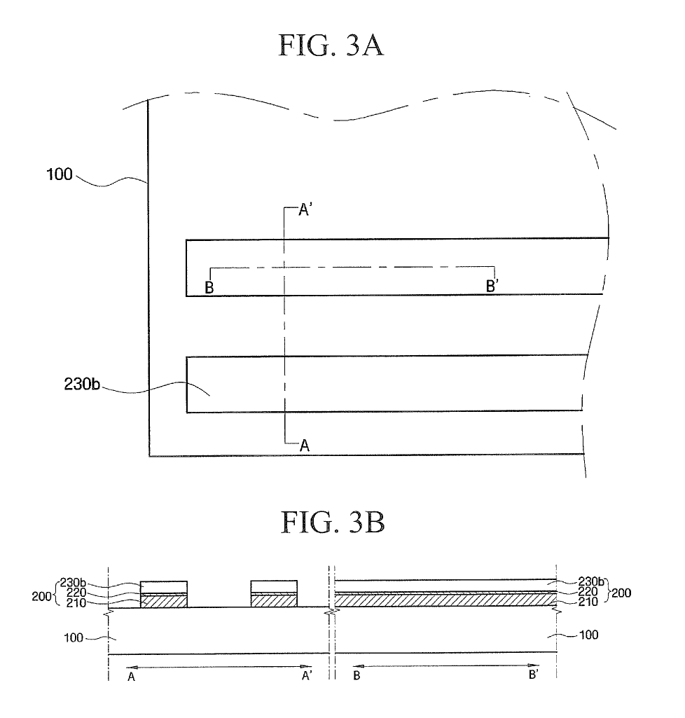

Referring to FIGS. 1, 3A, and 3B, in block S120, a structure 200 including a buffer layer 230b, a catalyst layer 220, and a lower interconnection layer 210 is formed by patterning the thin film 230a, the conductive layer 220a, and the conductive layer 210a illustrated in FIG. 2B. In order to pattern the thin film 230a, the conductive layer 220a and the conductive layer 210a, a photoresist pattern may be formed, and then, photolithography may be performed using the photoresist pattern. The structure 200 may be formed according to a desired lower interconnection layout. Referring to FIGS. 3A and 3B, a pair of structures 200 may be formed and extend in parallel.

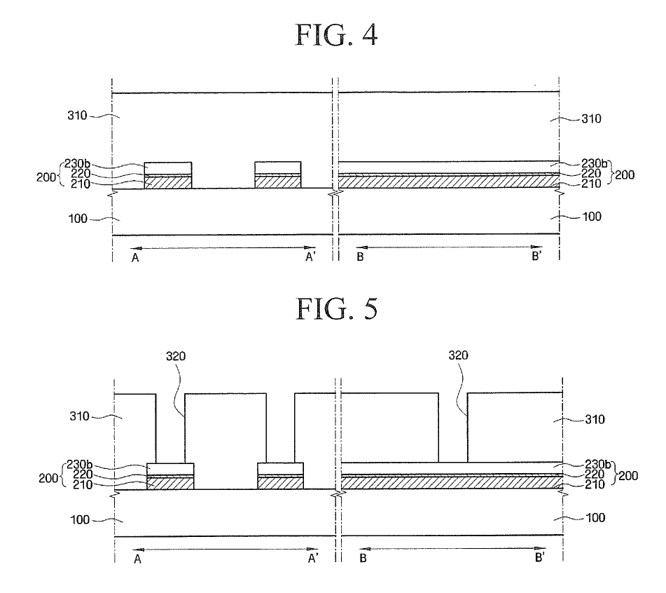

Referring to FIGS. 1 and 4, in block S130, an interlayer dielectric layer 310 is formed to cover the semiconductor substrate 100 and the buffer layer 230b. The interlayer dielectric layer 310 may be an oxide layer. Such a layer may exhibit poor adhesiveness to the catalyst layer 220. Therefore, if the interlayer dielectric layer 310 were to be formed directly on the catalyst layer 220, the interlayer dielectric layer 310 might be easily detached from the catalyst layer 220, thereby causing a defect. According to first embodiments of the present invention, however, direct contact of the interlayer dielectric layer 310 and the catalyst layer 220 may be limited by the buffer layer 230b formed on the catalyst layer 220. That is, the interlayer dielectric layer 310 is attached to the buffer layer 230b, which may have superior adhesiveness and may thereby reduce defect rates. After the formation of the interlayer dielectric layer 310, the interlayer dielectric layer 310 may be planarized by performing a chemical mechanical polishing (CMP) operation on the interlayer dielectric layer 310.

Referring to FIGS. 1 and 5, in block S140, a contact hole 320 is formed through the interlayer dielectric layer 310 so that the top surface of the buffer layer 230b is exposed through the contact hole 320. That is, the contact hole 320 is formed through the interlayer dielectric layer 310 so that the top surface of the structure 200 may be exposed. More specifically, the top surface of the buffer layer 230b of the structure 200 is partially exposed by the contact hole 320. The contact hole 320 may be formed by forming a photoresist pattern that exposes a portion on the interlayer dielectric layer 310 where the contact hole 320 is to be formed and etching using the photoresist pattern as a mask. The etching may be, for example, a dry etching process using the buffer layer 230b as an etching stopper. During the dry etching process, an etching gas having a high etch selectivity of the interlayer dielectric layer 310 to the buffer layer 230b may be used. In this manner, damage to the catalyst layer 220 may be limited.

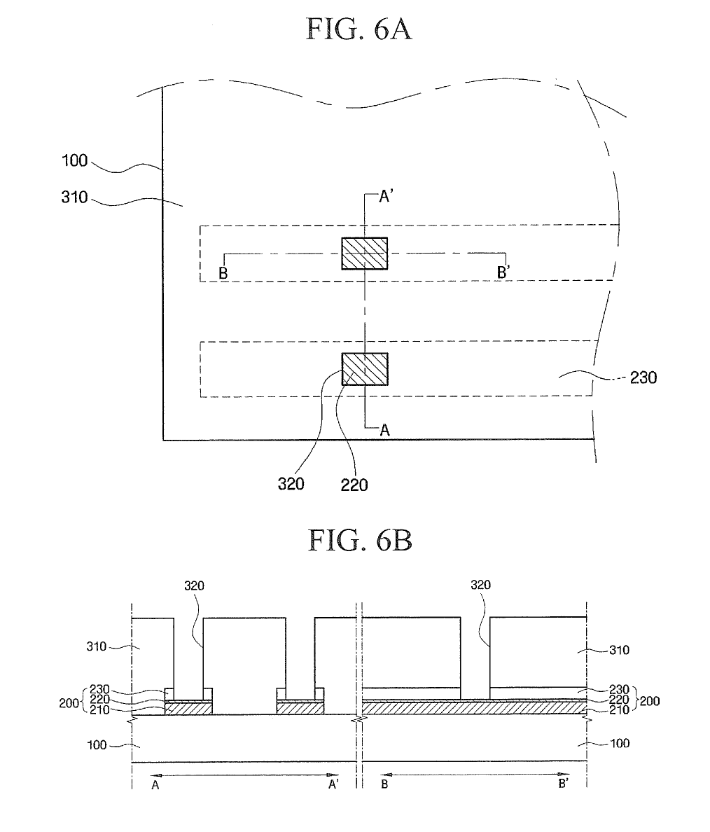

Referring to FIGS. 1, 6A, and 6B, in block S150, a portion of the buffer layer 230b exposed by the contact hole 320 is removed so that the top surface of the catalyst layer 220 is exposed. The exposed portion of the buffer layer 230b may be removed by, for example, a wet etching process. During a wet etching operation for removing the exposed portion of the buffer layer 230b, an etchant having a high etch selectivity of the buffer layer 230b to the catalyst layer 220 may be used. In this manner, the exposed portion of the buffer layer 230b is removed, and the catalyst layer 220 is exposed. During the wet etching operation for removing the exposed portion of the buffer layer 230b, the catalyst layer 220 may be partially etched away. Thus, the thickness of the conductive layer 220a formed as illustrated in FIG. 2A may be appropriately adjusted so that a sufficient catalyst layer thickness to grow carbon nanotubes stably may be secured after the wet etching operation for removing the exposed portion of the buffer layer 230b.

According to the first embodiments, it is possible to properly form a contact hole 320 and to minimize damage to the catalyst layer 220 by performing the formation of the contact hole 320 and the removal of the exposed portion of the buffer layer 230b separately. Also, it is possible to effectively protect the catalyst layer 220 by protecting the catalyst layer 220 during a dry etching process and subjecting the catalyst layer 220 only to a wet etching operation, which may cause less damage to the catalyst layer 220 than a dry etching process.

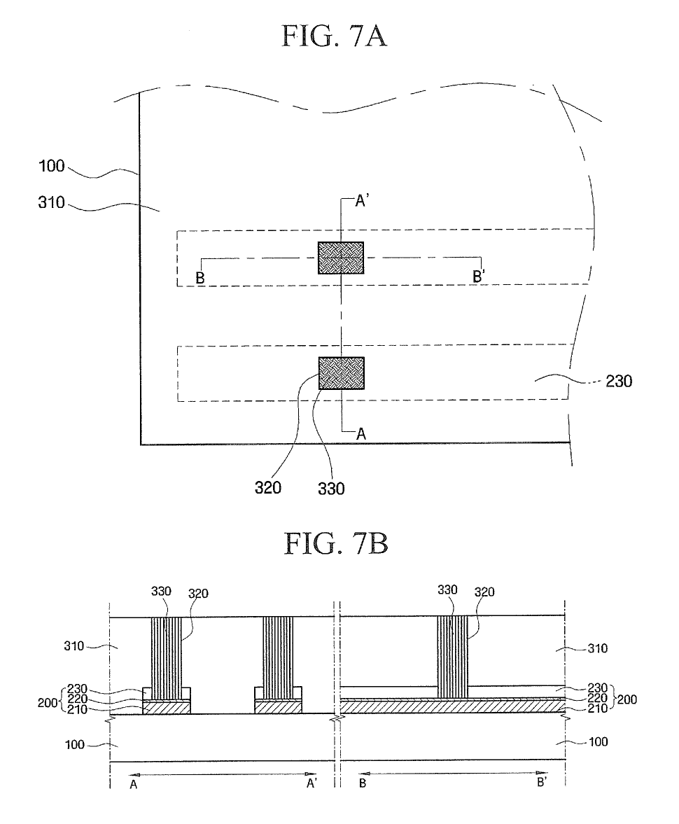

Referring to FIGS. 1, 7A and 7B, in block S160, carbon nanotubes 330 are grown from the catalyst layer 220 so that the contact hole 320 may be filled with the carbon nanotubes 330. The carbon nanotubes 330 may be grown using, for example, an electric discharge method, a laser deposition method, a plasma CVD method, or a thermochemical CVD method. For example, the carbon nanotubes 330 may be formed along a direction perpendicular to the top surface of the catalyst layer 220 using a thermochemical CVD method by supplying a carbon source gas and an inert gas into a reaction chamber at a temperature of about 500-900° C. CH₄, C₂H₂, C₂H₄, C₂H₆, CO, or CO₂ may be used as the carbon source gas, and H₂, N₂ or Ar may be used as the inert gas.

Thereafter, a CMP operation may be performed on the interlayer dielectric layer 310 and the carbon nanotubes 330 so that the top surfaces of the interlayer dielectric layer 310 and the carbon nanotubes 330 are planarized. An upper interconnection layer may be formed on the interlayer dielectric layer 310 and connected to the carbon nanotubes 330.

According to the first embodiments, it is possible to effectively protect the catalyst layer 220 by forming the buffer layer 230b on the catalyst layer 220. In addition, it is possible to prevent the catalyst layer 220 from being damaged during an etching operation for forming the contact hole 320 by using the buffer layer 230b as an etching stopper. Moreover, it is possible to prevent the interlayer dielectric layer 310 from directly contacting the catalyst layer 220 by forming the buffer layer 230b on the catalyst layer 220. Therefore, defect rates may be reduced and an integrated circuit device having improved properties may be produced by preventing the interlayer dielectric layer 310 from being detached from the underlying layers due to poor adhesiveness between the catalyst layer 220 and the interlayer dielectric layer 310.

An integrated circuit device according to further embodiments of the present invention will hereinafter be described in detail with reference to FIGS. 7A and 7B. FIG. 7A is a layout of an integrated circuit device according to further embodiments of the present invention, and FIG. 7B illustrates cross-sectional views respectively taken along lines A-A′ and B-B′ of FIG. 7A.

Referring to FIGS. 7A and 7B, the structure 200 including the lower interconnection layer 210, the catalyst layer 220, and the buffer layer 230 is formed on a semiconductor substrate 100. The catalyst layer 220 is formed on the lower interconnection layer 210, and the buffer layer 230 is formed on the catalyst layer 220 and has an opening therein that partially exposes the top surface of the catalyst layer 220. The buffer layer 230 serves as a buffer that can prevent the catalyst layer 220 from directly contacting the interlayer dielectric layer 310 formed on the structure 200. The opening in the buffer layer 230 exposes areas on which the carbon nanotubes 330 are to be formed.

The interlayer dielectric layer 310 is formed on the structure 200 and covers the structure 200 and the semiconductor substrate 100. The contact hole 320 is formed through the interlayer dielectric layer 310 so that the top surface of the catalyst layer 220 may be exposed. The contact hole 320 is filled with the carbon nanotubes 330.

In some embodiments of the present invention, the structure 200 is formed in which the lower interconnection layer 210, the catalyst layer 220, and the buffer layer 230 are sequentially deposited; the contact hole 320 is formed and partially exposes the catalyst layer 220; and the carbon nanotubes 330 are grown from a portion of the catalyst layer 220 exposed by the contact hole 320. The catalyst layer 220 except the exposed portion from which the carbon nanotubes 330 are grown is covered by the buffer layer 230. Thus, the catalyst layer 220 may be prevented from directly contacting the interlayer dielectric layer 310. Therefore, it is possible to prevent the interlayer dielectric layer 310 from being detached from the underlying layers due to poor adhesiveness between the catalyst layer 220 and the interlayer dielectric layer 310. In addition, it is possible to reduce defect rates and improve the properties of an integrated circuit device.

Methods of fabricating integrated circuit devices according to second embodiments of the present invention will now be described in detail with reference to FIGS. 1 through 7B. In the first and second embodiments of the present invention, like reference numerals represent like elements and, therefore, detailed descriptions of these like elements will not be repeated in light of the foregoing discussion of the first embodiments. The second embodiments differ from the first embodiments in that a portion of a buffer layer exposed by a contact hole is removed by dry etching. Detailed descriptions of operations S110 and S120 illustrated in FIG. 1 may be directly applied to the second embodiments. Thus, the description of the second embodiments will focus on block S130 and subsequent operations.

Referring to FIGS. 1 and 5, in block S130, an interlayer dielectric layer 310 is formed to cover a semiconductor substrate 100 and a buffer layer 230b. In block S140, a contact hole 320 is formed through the interlayer dielectric layer 310 so that the top surface of the buffer layer 230b may be partially exposed through the contact hole 320.

In detail, the contact hole 320 may be formed by forming a photoresist pattern that exposes an area on the interlayer dielectric layer 310 where the contact hole 320 is to be formed and etching using the photoresist pattern as a mask. The etching may be a dry etching process using the buffer layer 230b an etch stopper. For example, the etching may be a reactive ion etching operation. A reactive ion etching operation may provide high etching efficiency by supplying both an inert gas and a reactive gas into a reaction chamber so that a physical etching operation and a chemical etching operation may be simultaneously induced by the inert gas and the reactive gas, respectively.

During a dry etching process for forming the contact hole 320, an etching gas having a large etch selectivity of the interlayer dielectric layer 310 to the buffer layer 230b may be used. Thus, the buffer layer 230b may be prevented from being significantly etched while the interlayer dielectric layer 310 is etched away. For example, if the buffer layer 230b is a nitride layer and the interlayer dielectric layer 310 is an oxide layer, an etching process may be performed using an etching gas having a large etch selectivity of an oxide layer to a nitride layer as an etching gas so that only the interlayer dielectric layer 310 may be etched. That is, the buffer layer 230 may serve as an etching stopper.

The etching gas used in the dry etching process for forming the contact hole 320 may contain 50% inert gas. The inert gas may be Ar. That is, the amount of inert gas supplied during the dry etching process for forming the contact hole 320 may be greater than the amount of reactive gas supplied during the dry etching process for forming the contact hole 320. In this case, physical etch rate of etching gas may be increased, and thus, the removal of the interlayer dielectric layer 310 may be facilitated.

Referring to FIGS. 1, 6A and 6B, the exposed portion of the buffer layer 230 is removed so that the top surface of the catalyst layer 220 is exposed. The exposed portion of the buffer layer 230b may be removed by performing a dry etching process. For example, the exposed portion of the buffer layer 230b may be removed by performing a reactive ion etching process.

During a dry etching process for removing the exposed portion of the buffer layer 230b, an etching gas having a large etch selectivity of the buffer layer 230b to the interlayer dielectric layer 310 may be used. For example, if the buffer layer 230b is a nitride layer and the interlayer dielectric layer 310 is an oxide layer, the exposed portion of the buffer layer 230b may be removed by performing an etching process using a reactive gas having a large etch selectivity of a nitride layer to an oxide layer as an etching gas.

The etching gas used in the dry etching process for removing the exposed portion of the buffer layer 230b may contain less than 10% inert gas or no inert gas at all. That is, physical etch rate of the buffer layer 230b by inert gas is limited by supplying only a small amount of inert gas or supplying no inert gas at all. A large amount of reactive gas may be included in the etching gas used in the dry etching process for removing the exposed portion of the buffer layer 230b. In this case, the exposed portion of the buffer layer 230b may be removed through chemical etching.

The catalyst layer 220 may be formed thinly. If the catalyst layer 220 is damaged, stable formation of carbon nanotubes may not be possible. The catalyst layer 220 may be prevented from being significantly damaged during the dry etching process for removing the exposed portion of the buffer layer 230b by reducing the physical etch rate by inert gas and increasing the chemical etch rate by a reactive gas. During the etching operation for removing the exposed portion of the buffer layer 230b, the catalyst layer 220 may be partially etched away. Thus, the thickness of the conductive layer 220a formed as illustrated in FIG. 2A may be appropriately adjusted so that a sufficient catalyst layer thickness to grow carbon nanotubes stably may be secured even after the etching operation for removing the exposed portion of the buffer layer 230b.

According to the second embodiments, it is possible to effectively protect the catalyst layer 220 by forming the buffer layer 230 on the catalyst layer 220. More specifically, it is possible to prevent the catalyst layer 220 from being damaged by using the buffer layer 230 as an etching stopper during an etching operation for forming the contact hole 320 and removing the buffer layer 230 through chemical etching. In this manner, properties of an integrated circuit device may be improved by more stably growing carbon nanotubes.

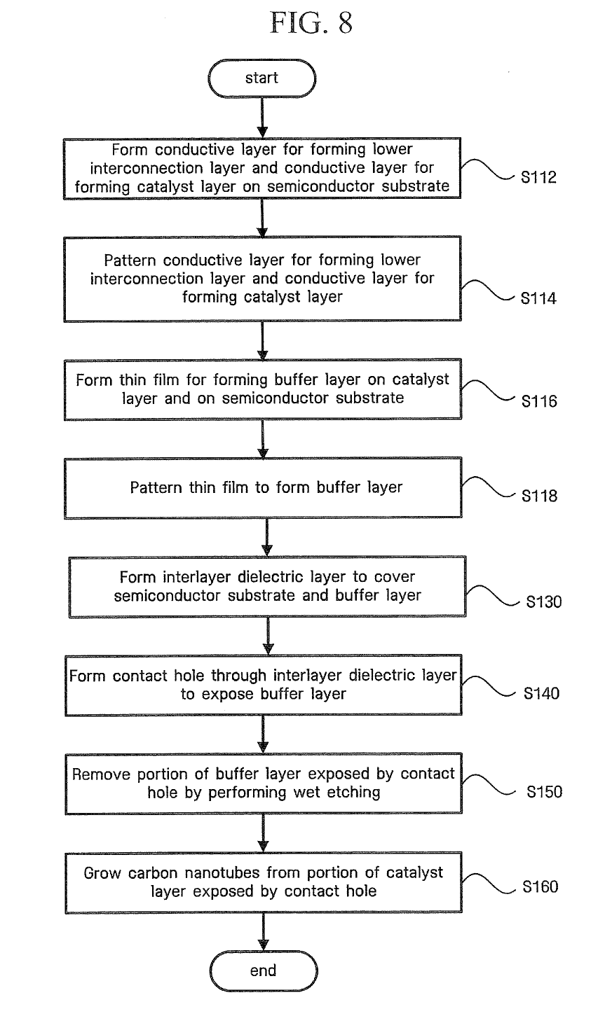

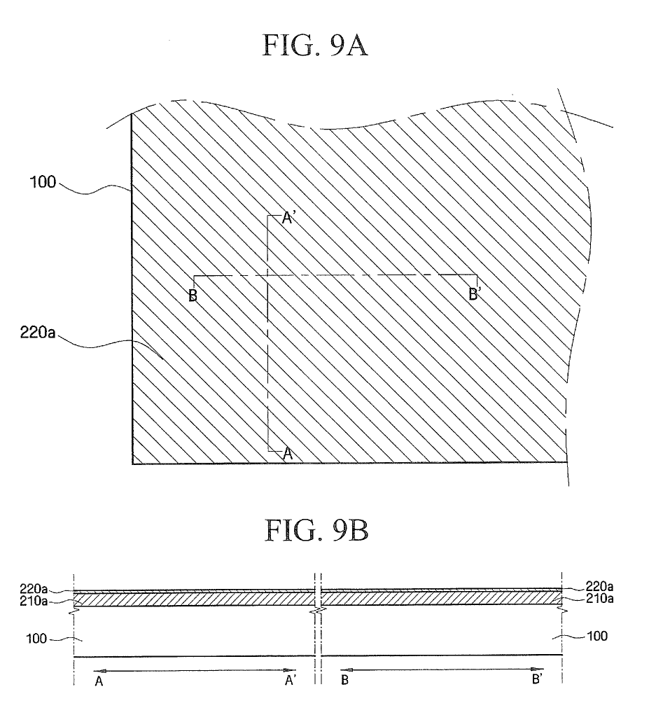

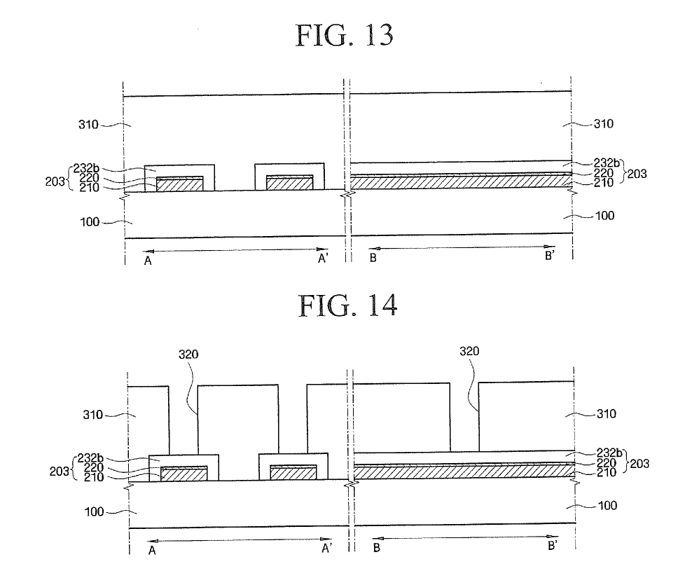

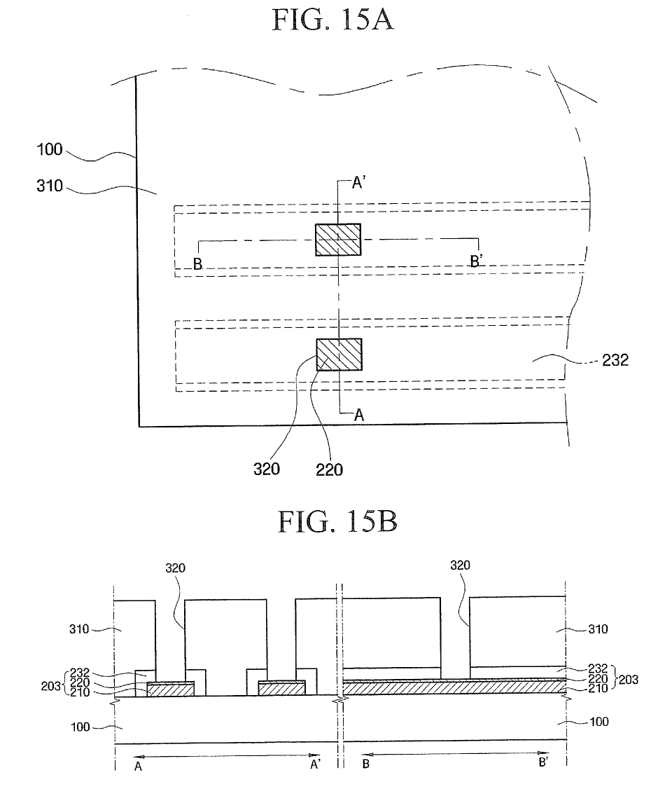

Method of fabricating an integrated circuit device according to third embodiments of the present invention will now be described in detail with reference to FIGS. 8 through 16B. FIG. 8 is a flowchart illustrating operations for fabricating integrated circuit devices according to some embodiments of the present invention, and FIGS. 9A through 16B include plan and cross-sectional views illustrating the operations of FIG. 8. In FIGS. 1 through 16B, like reference numerals represent like elements, and description of elements previously described will not be repeated.

Referring to FIGS. 8 through 9B, in block S112, a conductive layer 210a for forming a lower interconnection layer and a conductive layer 220a for forming a catalyst layer are sequentially formed on a semiconductor substrate 100. The formation of the conductive layers 210a and 220a may be the same as the formation of the conductive layers 210a and 220a described above with reference to FIGS. 2A and 2B.

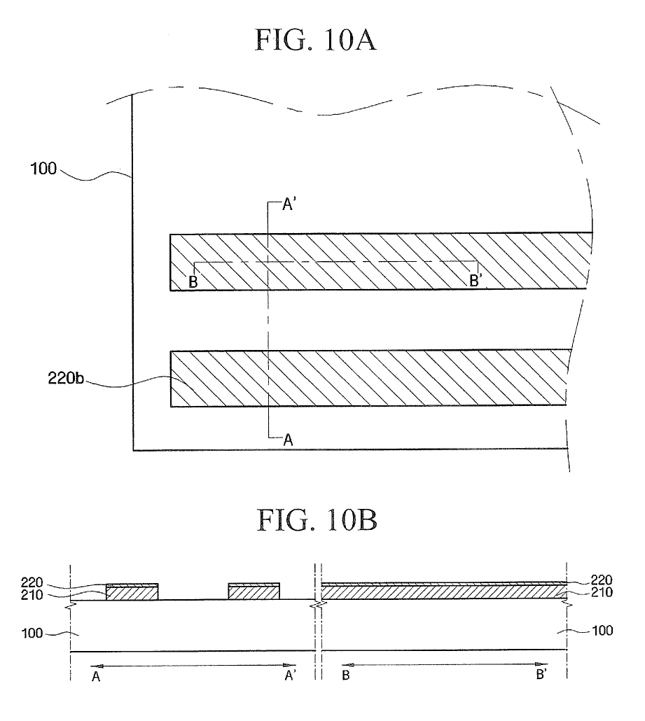

Referring to FIGS. 8, 10A and 10B, in block S114, a catalyst layer 220 and a lower interconnection layer 210 are formed by patterning the conductive layers 210a and 220a. The conductive layers 210a and 220a are patterned so that a desired lower interconnection layout may be obtained. Referring to FIG. 10A, a pair of catalyst layers 220 or a pair of lower interconnection layers 210 may be formed and may extend in parallel.

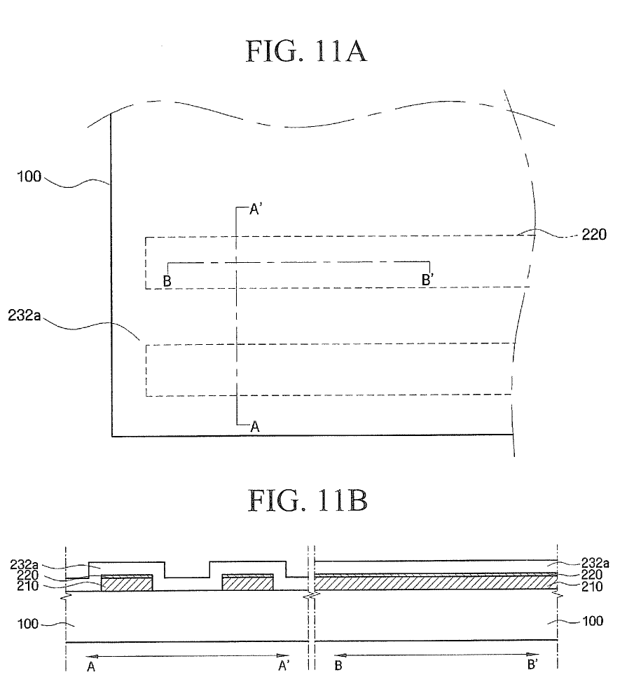

Referring to FIGS. 8, 11A and 11B, in block S116, a thin film 232a for forming a buffer layer is formed on the catalyst layer 220 and on the semiconductor substrate 100. The thin film 232a may conform to the top surfaces of the catalyst layer 220 and the semiconductor substrate 100. The thin film 232a may be formed using, for example, a CVD or PVD method. The thin film 232a may be formed of a conductive material, for example, a metal such as W, Al, TiN, Ti, or a combination thereof. The thin film 232a may be formed to a thickness of about 100-1000 Å. The thin film 232a may be formed of a material having excellent adhesiveness to an interlayer dielectric layer, which will be formed in a subsequent operation.

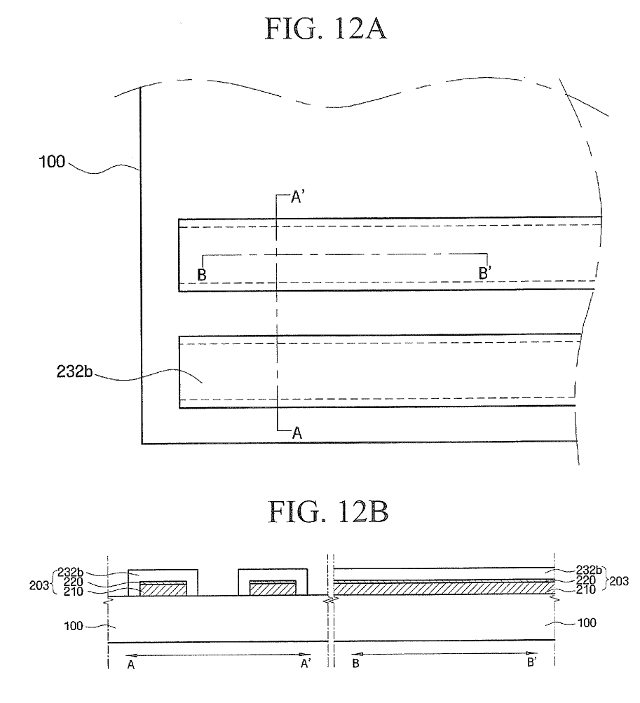

Referring to FIGS. 8, 12A and 12B, the thin film 232a is patterned, thereby forming a buffer layer 232b, which covers the top surface of the catalyst layer 220 and the lateral surfaces of the catalyst layer 220 and of the lower interconnection layer 210. As a result, a structure 203 is formed including the lower interconnection layer 210 and the catalyst layer 220, and the buffer layer 232b covers the top surface of the catalyst layer 220 and the lateral surfaces of the catalyst layer 220 and of the lower interconnection layer 210.

The thin film 232a is patterned such that the width of the buffer layer 232b may be greater than the width of the catalyst layer 220 and such that the catalyst layer 220 is covered by the buffer layer 232b. That is, the buffer layer 232b is formed to cover the top surface and lateral surfaces of the catalyst layer 220. In the structure 203, because the catalyst layer 220 is covered by the buffer layer 232b, portions of the catalyst layer 220 other than a portion exposed by a contact hole may be prevented from being exposed during subsequent processes.

Referring to FIGS. 8 and 13 through 16B, in block S130, an interlayer dielectric layer 310 is formed to cover the semiconductor substrate 100 and the structure 203. In block S140, a contact hole 320 is formed through the interlayer dielectric layer 310 so that the top surface of the buffer layer 232b is exposed through the contact hole 320. In block Si 50, a portion of the buffer layer 232b exposed by the contact hole 320 is removed so that the top surface of the catalyst layer 220 is exposed. In block S160, carbon nanotubes 330 are grown from a portion of the catalyst layer 220 exposed by the contact hole 320. Operations S130 through S160 may be the same as their respective counterparts in the first embodiments, and thus, detailed descriptions thereof will not be repeated.

Variations of the embodiments illustrated in FIGS. 8 through 16B will hereinafter be described in detail. A variation may involve an operation, like the block S140 of FIG. 1, in which a contact hole 320 is formed through an interlayer dielectric layer 310 so that the top surface of a buffer layer 232b is exposed; an operation, like the block S150 of FIG. 1, in which a portion of the buffer layer 232b exposed by the contact hole 320 is removed so that the top surface of a catalyst layer 220 may be partially exposed.

More specifically, in some variations of the third embodiments, a contact hole 320 may be formed by performing a dry etching process using an etching gas having a high etch selectivity of an interlayer dielectric layer 310 to a buffer layer 232b and using the buffer layer 232b as an etching stopper. The etching gas used in the dry etching process for forming the contact hole 320 may contain 50% inert gas.

In some variations of the third embodiments, a portion of the buffer layer 232b exposed by the contact hole 320 may be removed by performing a dry etching process using an etching gas having a high etch selectivity of the buffer layer 232b to the interlayer dielectric layer 310. The etching gas used in the dry etching process for removing the exposed portion of the buffer layer 232b may contain less than 10% inert gas or no inert gas at all so that the rate at which the buffer layer 232b is chemically etched by a reactive gas may be increased.

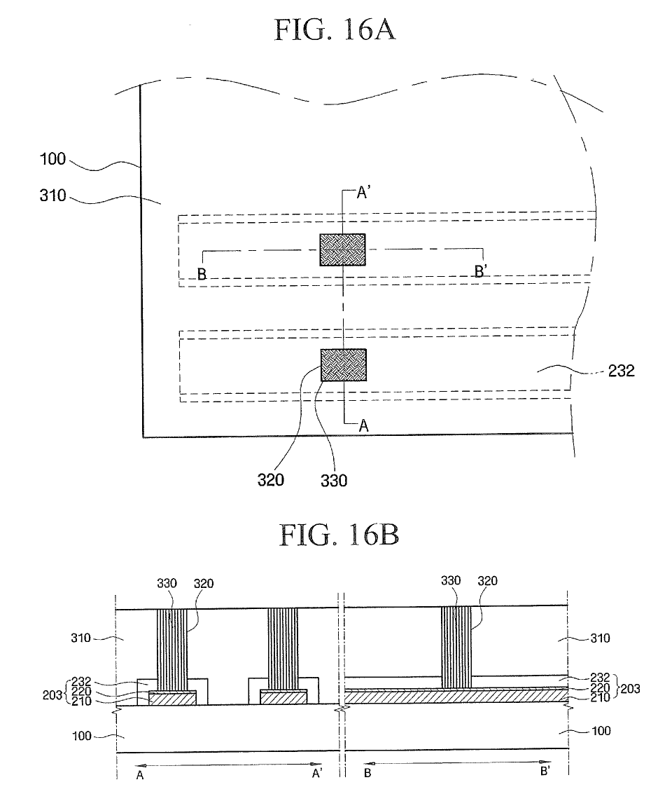

An integrated circuit device according to further embodiments of the present invention will hereinafter be described in detail with reference to FIGS. 16A and 16B. FIG. 16A is a layout of an integrated circuit device according to some embodiments of the present invention, and FIG. 16B illustrates cross-sectional views respectively taken along lines A-A′ and B-B′ of FIG. 16A.

In FIGS. 7A and 7B and 16A and 16B, like reference numerals represent like elements, and thus, descriptions thereof will not be repeated. The integrated circuit device illustrated in FIGS. 16A and 16B is different from the integrated circuit device illustrated in FIGS. 7A and 7B in that it includes a buffer layer covering a lower interconnection layer and a catalyst layer.

Referring to FIGS. 16A and 16B, the structure 203 in which the lower interconnection layer 210, the catalyst layer 220 and the buffer layer 232 are sequentially deposited is formed on the semiconductor substrate 100. The buffer layer 232 covers the lower interconnection layer 210 and the catalyst layer 220. More specifically, the buffer layer 232 covers part of the top surface of the catalyst layer 220 and lateral surfaces of the catalyst layer 220 and the lower interconnection layer 210. The buffer layer 232 exposes part of the top surface of the catalyst layer 220 through the contact hole 320. Accordingly, portions of the catalyst layer 220 other than a portion from which carbon nanotubes 330 are grown are covered by the buffer layer 232. In the integrated circuit device illustrated in FIGS. 16A and 16B, the buffer layer 232 covers not only part of the top surface of the catalyst layer 220 but also lateral surfaces of the catalyst layer 220, which may prevent the catalyst layer 220 from directly contacting the interlayer dielectric layer 310. Therefore, it is possible to effectively prevent the interlayer dielectric layer 310 from being detached from the underlying layers due to poor adhesiveness between the catalyst layer 220 and the interlayer dielectric layer 310. As a result, it is possible to reduce defect rates and improve the properties of an integrated circuit device.

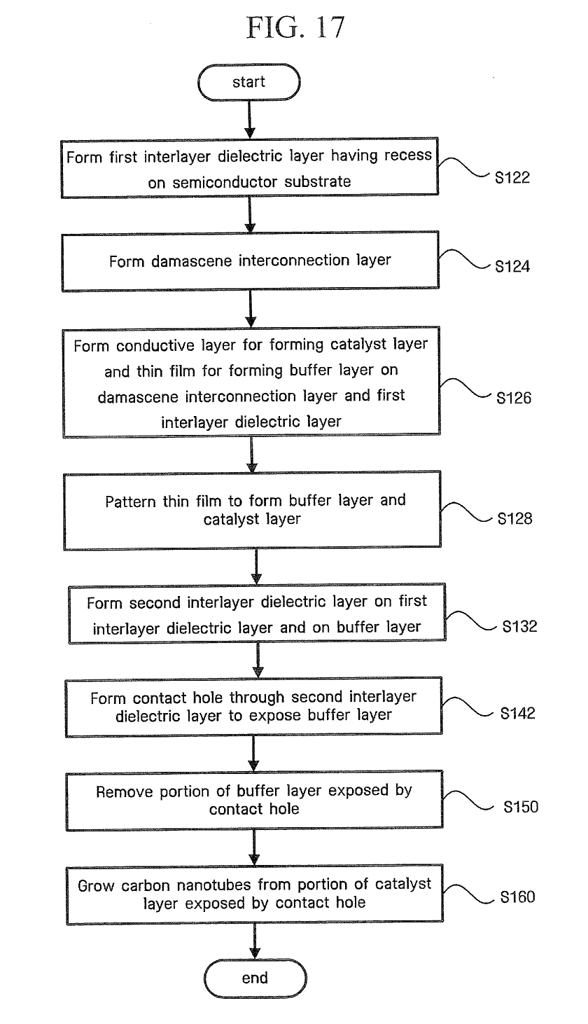

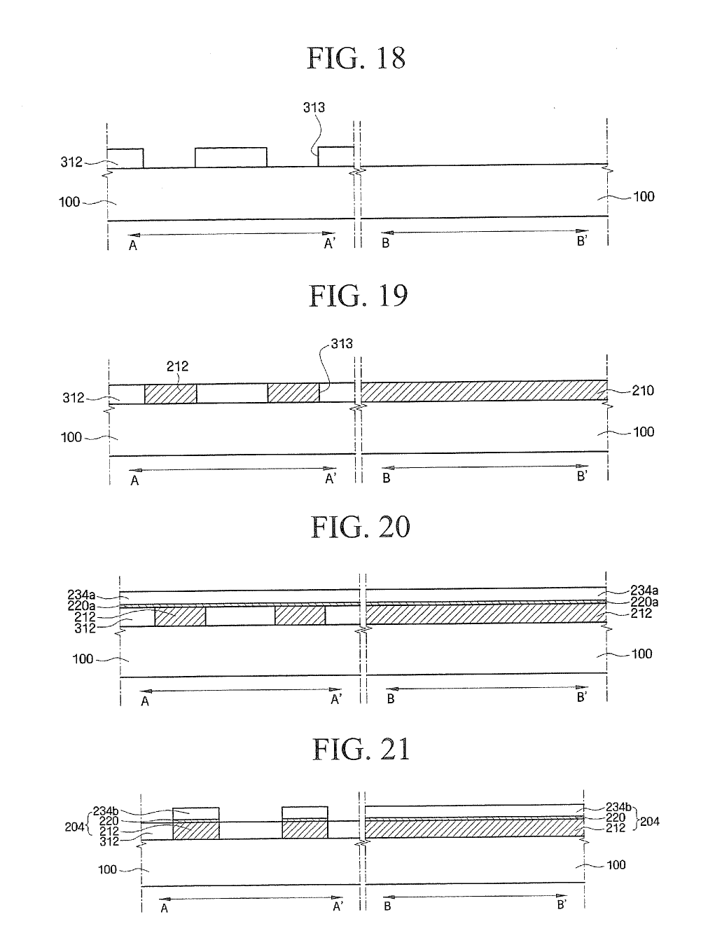

Methods of fabricating integrated circuit devices according to fourth embodiments of the present invention will hereinafter be described in detail with reference to FIGS. 17 through 25B. FIG. 17 is a flowchart illustrating operations for fabricating an integrated circuit device according to some embodiments of the present invention, and FIGS. 18 through 25B include plan and cross-sectional views illustrating operations in FIG. 17. In the first and fourth embodiments, like reference numerals represent like elements, and therefore, detailed descriptions thereof will not be repeated.

Referring to FIGS. 17 and 18, a first interlayer dielectric layer 312 having a recess 313 is formed on a semiconductor substrate 100. In detail, the first interlayer dielectric layer 312 is deposited on the semiconductor substrate 100, and is planarized using, for example, a CMP method. Thereafter, a photoresist pattern that exposes an area on the first interlayer dielectric layer 312 where the recess 313 is to be formed is formed, and etching is performed using the photoresist pattern, thereby completing the formation of the first interlayer dielectric layer 312 having the recess 313. The first interlayer dielectric layer 312 may be an oxide layer.

Referring to FIGS. 17 and 19, in block S124, a damascene interconnection layer 212 is formed so that the recess 313 may be filled with the damascene interconnection layer 212. In detail, a conductive layer is deposited on the first interlayer dielectric layer 312 using a CVD or PVD method. The conductive layer may be formed of, for example, a metal such as Cu, W, Al, TiN, Ti, or a combination thereof. The deposition of the conductive layer may continue until the recess 313 is completely filled with the conductive layer. Thereafter, a planarization operation such as a CMP operation is performed on the conductive layer so that portions of the conductive layer directly on the interlayer dielectric layer 312 may be removed. In this manner, the damascene interconnection layer 212 may be formed.

Referring to FIGS. 17 and 20, in block S126, a conductive layer 220a for forming a catalyst layer and a thin film 234a for forming a buffer layer are formed on the damascene interconnection layer 212 and on the first interlayer dielectric layer 312.

The formation of the conductive layer 220a and the thin film 234a is the same as the formation of their respective counterparts in the first embodiment.

Referring to FIGS. 17 and 21, in block S218, a catalyst layer 220 and a buffer layer 234b are formed on the damascene interconnection layer 212 by patterning the thin film 234a and the conductive layer 220a. As a result of block S218, a structure 204 is formed in which the catalyst layer 220 and the buffer layer 234b are formed on the lower interconnection layer 210. In the structure 204, because the buffer layer 234b is formed on the catalyst layer 220, the catalyst layer 220 may be protected by the buffer layer 234b.

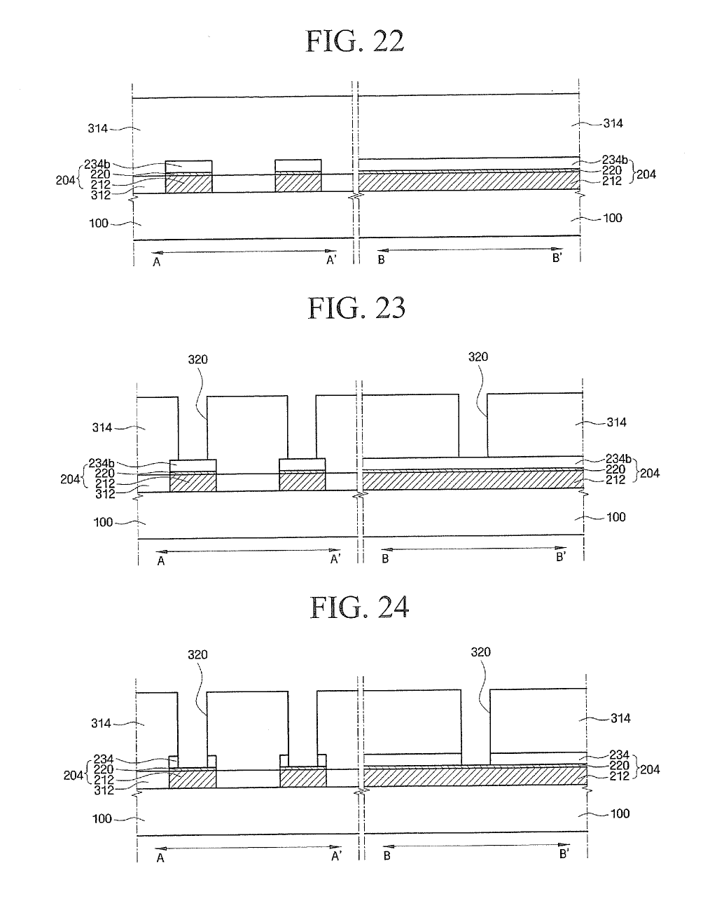

Referring to FIGS. 17 and 22, in block S132, a second interlayer dielectric layer 314 is formed on the first interlayer dielectric layer 312 and on the buffer layer 234b. The second interlayer dielectric layer 314 may be an oxide layer. After the formation of the second interlayer dielectric layer 314, a CMP operation may be performed on the second interlayer dielectric layer 314 so that the top surface of the second interlayer dielectric layer 314 may be planarized.

Referring to FIGS. 17 and 23, in block S142, a contact hole 320 is formed through the second interlayer dielectric layer 314 so that the top surface of the buffer layer 234b may be exposed.

Referring to FIGS. 17, and 23 through 25B, in block S150, a portion of the buffer layer 234b exposed by the contact hole 320 is removed so that the top surface of the catalyst layer 220 may be exposed. In block S160, carbon nanotubes 330 are grown from a portion of the catalyst layer 220 exposed by the contact hole 320 so that the contact hole 320 may be filled with the carbon nanotubes 320. Operations S150 and S160 may be the same as their respective counterparts in the first embodiments, and thus, detailed descriptions thereof will not be repeated.

A variation such operations will now be described in detail. A variation of the fourth embodiments, like the second embodiments, may involve operations, such as block S140 of FIG. 1, in which a contact hole 320 is formed through a second interlayer dielectric layer so that the top surface of a buffer layer 234b may be partially exposed, and operations, such as block S150 of FIG. 1, in which a portion of the buffer layer 234b exposed by the contact hole 320 is removed so that the top surface of a catalyst layer 220 may be partially exposed.

More specifically, in some embodiments, a contact hole 320 may be formed by performing a dry etching process using an etching gas having a high etch selectivity of an interlayer dielectric layer 310 to a buffer layer 234b and using the buffer layer 234b as an etching stopper. The etching gas used in the dry etching process for forming the contact hole 320 may contain 50% inert gas.

In some variations of the third embodiments, a portion of the buffer layer 234b exposed by the contact hole 320 may be removed by performing a dry etching process using an etching gas having a high etch selectivity of the buffer layer 234b to the interlayer dielectric layer 310. The etching gas used in the dry etching process for removing the exposed portion of the buffer layer 234b may contain less than 10% inert gas or no inert gas at all so that the rate at which the buffer layer 234b is chemically etched by a reactive gas may be increased.

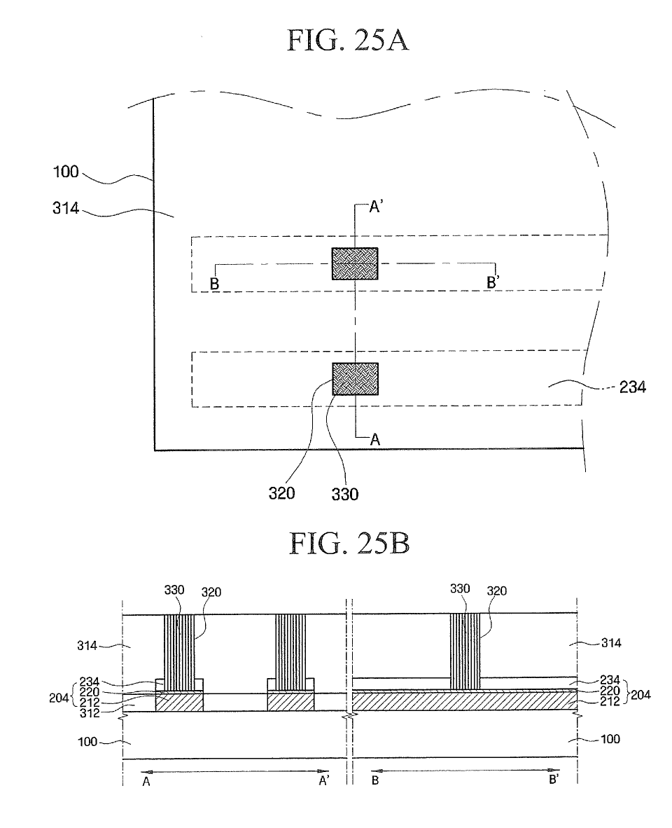

An integrated circuit device according to further embodiments of the present invention will hereinafter be described in detail with reference to FIGS. 25A and 25B. FIG. 25A is a layout of an integrated circuit device according to some embodiments of the present invention, and FIG. 25B illustrates cross-sectional views respectively taken along lines A-A′ and B-B′ of FIG. 25A. In FIGS. 7A and 7B and 25A and 25B, like reference numerals represent like elements, and thus, detailed descriptions thereof will not be repeated. The integrated circuit device illustrated in FIGS. 25A and 25B differs from the integrated circuit device illustrated in FIGS. 7A and 7B in that it includes a damascene interconnection layer, instead of a lower interconnection layer.

Referring to FIGS. 25A and 25B, the structure 204 including the damascene interconnection layer 212, the catalyst layer 220, and the buffer layer 234 is disposed on the semiconductor substrate 100. The damascene interconnection layer 212 is formed in the first interlayer dielectric layer 312, and the catalyst layer 220 and the buffer layer 234 are formed in the second interlayer dielectric layer 314.

In the integrated circuit device illustrated in FIGS. 25A and 25B, the structure 204 including the damascene interconnection layer 212, the catalyst layer 220, and the buffer layer 234 is formed, the catalyst layer 220 is partially exposed through a contact hole above the structure 204, and the carbon nanotubes 330 are grown from the exposed portion of the catalyst layer 220. Portions of the catalyst layer 220 other than the exposed portion from which the carbon nanotubes 330 are grown are covered by the buffer layer 234. Accordingly, the catalyst layer 220 may be prevented from directly contacting the second interlayer dielectric layer 314. That is, it is possible to prevent the second interlayer dielectric layer 314 from being detached from the underlying layers due to poor adhesiveness between the catalyst layer 220 and the second interlayer dielectric layer 314. Therefore, it is possible to enhance the reliability of an integrated circuit device.

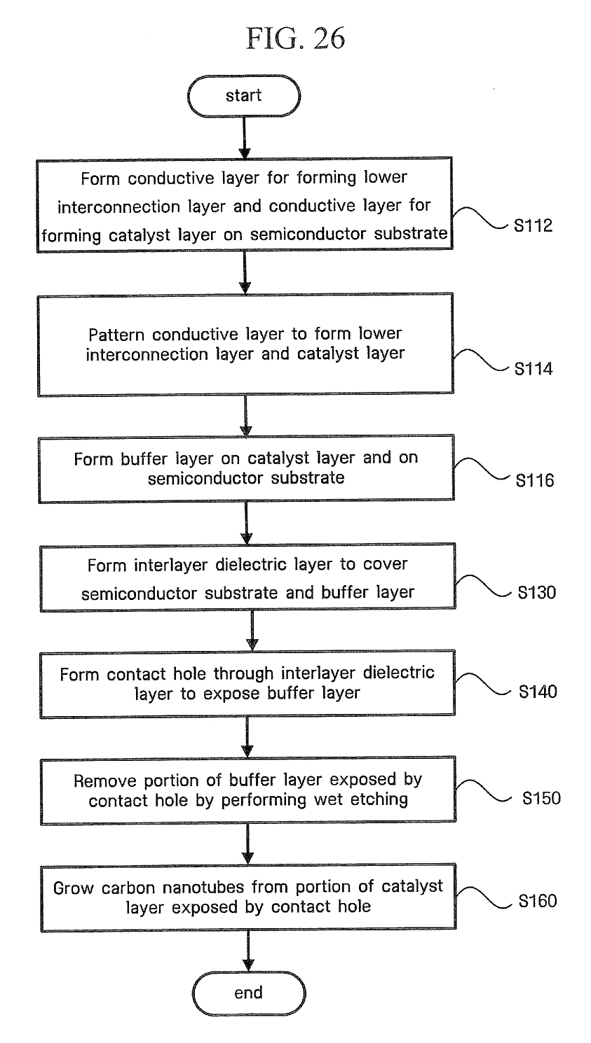

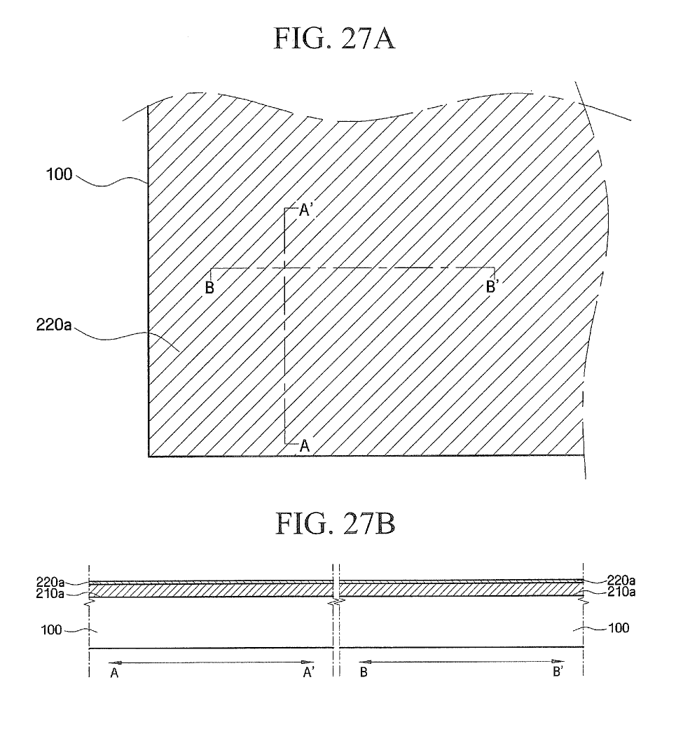

Methods of fabricating integrated circuit devices according to fifth embodiments of the present invention will hereinafter be described in detail with reference to FIGS. 26 through 32B. FIG. 26 is a flowchart illustrating operations for fabricating an integrated circuit device according to some embodiments of the present invention, and FIGS. 27A through 33B are plan and cross-sectional views illustrating the operations of FIG. 26. In the first and fifth embodiments, like reference numerals represent like elements, and therefore, detailed descriptions thereof will not be repeated.

Referring to FIGS. 26 through 27B, in block S112, a conductive layer 210a for forming a lower interconnection layer and a conductive layer 220a for forming a catalyst layer are formed on a semiconductor substrate 100.

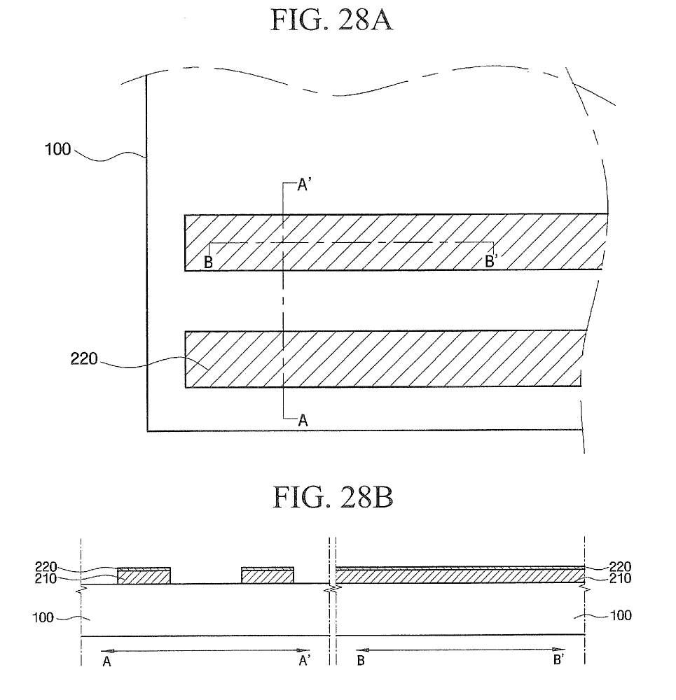

Referring to FIGS. 26, and 28A and 28B, in block S114, a catalyst layer 220 and a lower interconnection layer 210 are formed by patterning the conductive layer 220a and the conductive layer 210a. In detail, in order to pattern the conductive layers 220a and the conductive layer 210a, a photoresist pattern having a desired shape may be formed on the conductive layer 220a, and etching may be performed using the photoresist pattern as a mask.

The catalyst layer 220 and the lower interconnection layer 210 may be formed according to a desired lower interconnection layout. Referring to FIGS. 28A and 28B, a pair of catalyst layers 220 or lower interconnection layers 210 may extend in parallel.

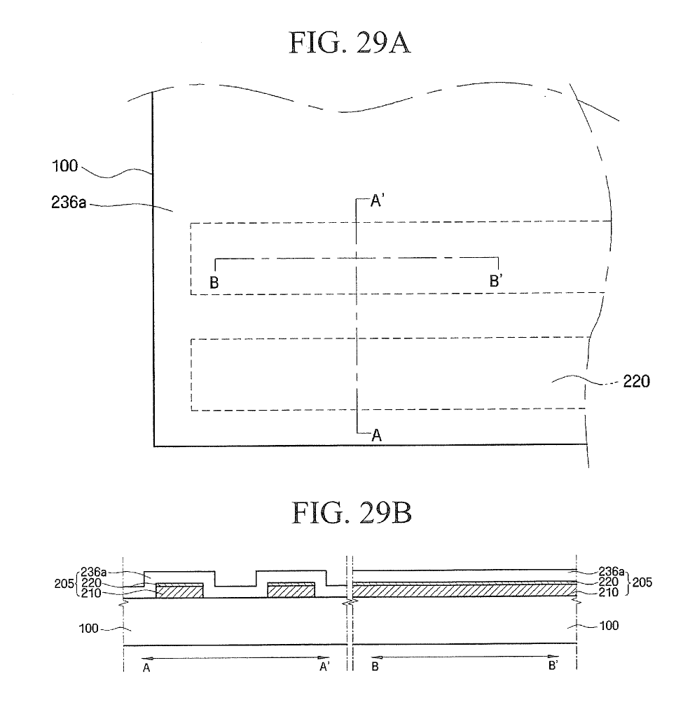

Referring to FIGS. 26, and 29A and 29B, in block S116, a buffer layer 236a is formed on the catalyst layer 220 and on the semiconductor substrate 100. In detail, the buffer layer 236a is formed on the entire surface of the semiconductor substrate 100 on which the catalyst layer 220 and the lower interconnection layer 210 are formed. The buffer layer 236a may be formed using, for example, a CVD or PVD process. The buffer layer 236a may be an dielectric layer, for example, a nitride layer. The buffer layer 236a may be formed to a thickness of about 300-1000 Å.

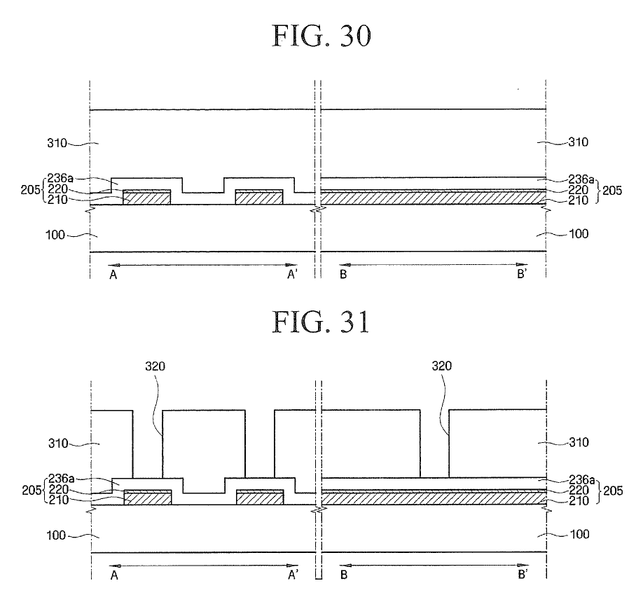

Referring to FIGS. 26 and 30, in block S130, an interlayer dielectric layer 310 is formed on the buffer layer 236a. The interlayer dielectric layer 310 may be an oxide layer. The interlayer dielectric layer 310 may be formed using a CVD method. The interlayer dielectric layer 310 may be planarized using a CMP process.

Referring to FIGS. 26 and 31, in block S140, a contact hole 320 is formed through the interlayer dielectric layer 310 so that the top surface of the buffer layer 236a may be partially exposed. In detail, the contact hole 320 is formed on the buffer layer 236a through the interlayer dielectric layer 310. The contact hole 320 may be formed by forming a photoresist pattern that exposes an area on the interlayer dielectric layer 310 where the contact hole 320 is to be formed and etching using the photoresist pattern as a mask. The etching may be a dry etching process using the buffer layer 236a as an etching stopper. During a dry etching process for forming the contact hole 320, an etching gas having a large etch selectivity of the interlayer dielectric layer 310 to the buffer layer 236a may be used. In this case, the buffer layer 236a is not etched, and only the interlayer dielectric layer 310 is etched. For example, if the buffer layer 236a is a nitride layer and the interlayer dielectric layer 310 is an oxide layer, an etching process may be performed using a reactive gas having a large etch selectivity of an oxide layer to a nitride layer so that only the interlayer dielectric layer 310 may be etched. In this case, the buffer layer 236a may serve as an etching stopper.

The etching gas used in the dry etching process for forming the contact hole 320 may contain more than 50% inert gas. The inert gas may be Ar. The inert gas content of the etching gas used in the dry etching process for forming the contact hole 320 may be greater than the reactive gas content of the etching gas used in the dry etching process for forming the contact hole 320. In this case, the rate at which the interlayer dielectric layer 310 is physically etched may be increased, and thus, the removal of the interlayer dielectric layer 310 may be facilitated.

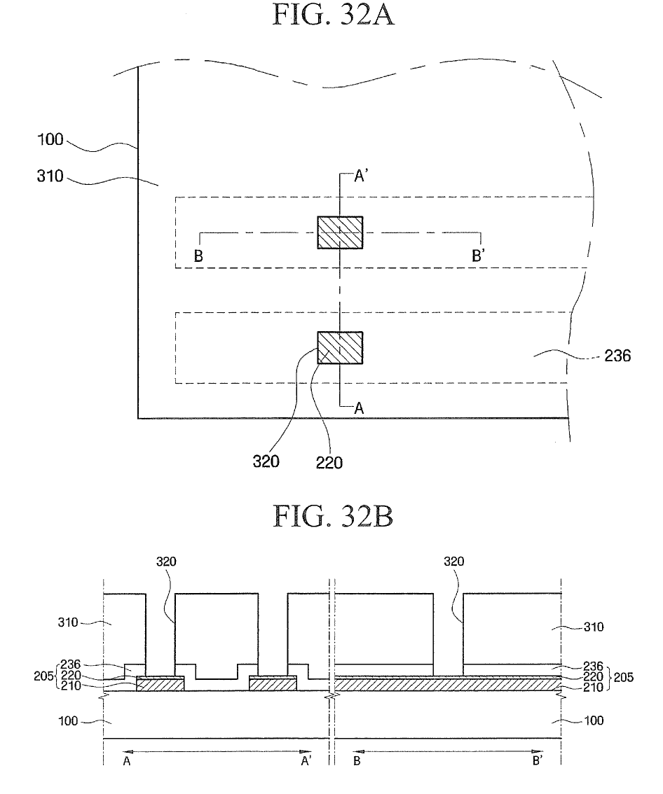

Referring to FIGS. 26, and 32A and 32B, in block S150, a portion of the buffer layer 236a exposed by the contact hole 320 is removed so that the top surface of the catalyst layer 220 may be partially exposed. The removal of the exposed portion of the buffer layer 236a may be performed using a dry etching method, for example, a reactive ion etching method.

During a dry etching process for removing the exposed portion of the buffer layer 236a, an etching gas having a high etch selectivity of the buffer layer 236a to the interlayer dielectric layer 310 may be used. In this case, the interlayer dielectric layer 310 is not etched, and only the buffer layer 236a is etched. For example, if the buffer layer 236a is a nitride layer and the interlayer dielectric layer 310 is an oxide layer, an etching operation may be performed using a reactive gas having a high etch selectivity of a nitride layer to an oxide layer.

The etching gas used in the dry etching process for removing the exposed portion of the buffer layer 236b may contain less than 10% inert gas or no inert gas at all. That is, physical etch rate of the buffer layer 230b is limited by supplying only a small amount of inert gas or supplying no inert gas at all. A large amount of reactive gas may be included in the etching gas used in the dry etching process for removing the exposed portion of the buffer layer 230b so that the buffer layer 236a may be chemically etched.

The catalyst layer 220 may be formed thinly. If the catalyst layer 220 is damaged, the formation of carbon nanotubes may not be able to be stably performed. The catalyst layer 220 may be prevented from being significantly damaged during the dry etching process for removing the exposed portion of the buffer layer 236b by reducing the physical etch rate of the buffer layer 230b and removing the exposed portion of the buffer layer 236b through chemical etching caused by an reactive gas.

During the dry etching process for removing the exposed portion of the buffer layer 236b, the catalyst layer 220 may be partially etched away. Thus, the thickness of the conductive layer 220a illustrated in FIG. 2A may be appropriately adjusted so that a sufficient catalyst layer thickness to grow carbon nanotubes stably may be secured even after the dry etching process for removing the exposed portion of the buffer layer 236b.

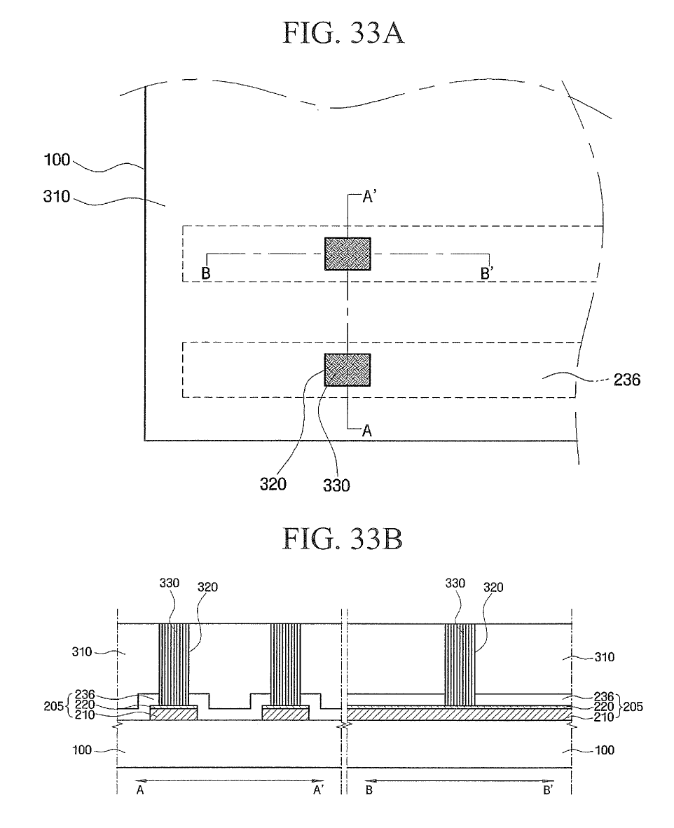

Referring to FIGS. 26 and 33A and 33B, in block S160, carbon nanotubes 330 are grown from a portion of the catalyst layer 220 exposed by the contact hole 320 so that the contact hole 320 may be filled with the carbon nanotubes 330. A CMP operation may be performed so that the top surfaces of the interlayer dielectric layer 310 and the carbon nanotubes 330 may be planarized. An upper interconnection layer (not shown) may be formed on the interlayer dielectric layer 310 so as to be connected to the carbon nanotubes 330.

According to the fifth embodiments, it is possible to effectively protect the catalyst layer 220 by forming the buffer layer 236 on the catalyst layer 220. Also, it is possible to protect the catalyst layer 220 from being damaged by using the buffer layer 236 as an etching stopper during an etching operation for forming the contact hole 320 and removing the buffer layer 236 through chemical etching. Therefore, it is possible to stably grow carbon nanotubes and to thus enhance the properties of an integrated circuit device.

Integrated circuit device according to further embodiments of the present invention will hereinafter be described in detail with reference to FIGS. 32A and 32B. FIG. 32A is a layout of an integrated circuit device according to some embodiments of the present invention, and FIG. 32B illustrates cross-sectional views respectively taken along lines A-A′ and B-B′ of FIG. 32A.

Referring to FIGS. 32A and 32B, the structure 205 including the lower interconnection layer 210 and the catalyst layer 220 is formed on the semiconductor substrate 100. The buffer layer 236 is formed on the structure 205 and on the semiconductor substrate 100 and exposes part of the top surface of the catalyst layer 220.

The interlayer dielectric layer 310 is formed on the buffer layer 236. The contact hole 320 is formed through the interlayer dielectric layer 310 so that the top surface of the catalyst layer 220 may be exposed. The contact hole 320 is filled with the carbon nanotubes 330.

In the integrated circuit device illustrated in FIGS. 32A and 32B, the structure 205 including the lower interconnection layer 210 and the catalyst layer 220 is formed, and the buffer layer 236 is formed on the structure 205 and partially exposes the top surface of the catalyst layer 220. The buffer layer 236 can protect the catalyst layer 220. Therefore, it is possible to stably grow carbon nanotubes and thus to enhance the properties of an integrated circuit device.

As described above, the present invention may provide at least the following advantages.

First, it is possible to protect a catalyst layer during the manufacture of an integrated circuit device by forming a buffer layer on the catalyst layer.

Second, it is possible to prevent a catalyst layer from being damaged during the formation of a contact hole by using a buffer layer as an etching stopper during an etching operation for forming a contact hole.

Third, it is possible to prevent a catalyst layer and an interlayer dielectric layer from directly contacting each other by forming a conductive buffer layer on the catalyst layer. Therefore, it is possible to prevent the interlayer dielectric layer from being detached from the underlying layers due to poor adhesiveness between the catalyst layer and the interlayer dielectric layer and thus to manufacture an integrated circuit device having improved properties.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. The invention is defined by the following claims.

1. A method of fabricating an integrated circuit device, the method comprising:
forming a stack comprising an interconnection layer on a substrate, a catalyst layer on the interconnection layer and a buffer layer on the catalyst layer;
forming an interlayer dielectric layer on the buffer layer;
forming a hole through the interlayer dielectric layer to expose a portion of the buffer layer;
removing the exposed portion of the buffer layer to expose a portion of the catalyst layer; and
growing carbon nanotubes on the exposed portion of the catalyst layer.

2. The method of claim 1:
wherein forming a hole through the interlayer dielectric layer to expose a portion of the buffer layer comprises performing a first etching process using the buffer layer as an etching stopper; and
wherein removing the exposed portion of the buffer layer to expose a portion of the catalyst layer comprises performing a second etching process.

3. (canceled)

4. The method of claim 2, wherein the first etching process comprises a dry etching process and the second etching process comprises a wet etching process.

5. The method of claim 2, wherein the first and second etching processes comprise respective different dry etching processes.

6.-8. (canceled)

9. The method of claim 2, wherein the first etching process comprises dry etching with an etching gas that contains more than 50% inert gas.

10. The method of claim 9, wherein the second etching process comprises dry etching with an etching gas that contains less than 10% inert gas.

11.-13. (canceled)

14. The method of claim 1, wherein forming a stack comprising an interconnection layer on a substrate, a catalyst layer on the interconnection layer and a buffer layer on the catalyst layer comprises:
depositing a conductive material layer on the substrate;
depositing a catalyst material layer on the conductive layer;
depositing a buffer material layer on the catalyst material layer; and
patterning the buffer material layer, the catalyst material layer and the conductive material layer to form the stack.

15. The method of claim 1, wherein forming a stack comprising an interconnection layer on a substrate, a catalyst layer on the interconnection layer and a buffer layer on the catalyst layer comprises:
depositing a conductive material layer on the substrate;
depositing a catalyst material layer on the conductive layer;
patterning the conductive material layer and the catalyst material layer to form a catalyst pattern on a conductive pattern;
depositing a buffer material layer conforming to a top surface of the catalyst pattern and sidewalls of the catalyst pattern and the conductive pattern.

16. The method of claim 15, further comprising patterning the buffer material layer to expose a portion of the substrate adjacent the sidewalls of the catalyst pattern and the conductive pattern.

17. The method of claim 1, wherein forming a stack comprising an interconnection layer on a substrate, a catalyst layer on the interconnection layer and a buffer layer on the catalyst layer comprises:
forming a damascene conductive layer in a dielectric layer on the substrate;
depositing a catalyst material layer on the conductive layer;
depositing a buffer material layer on the catalyst material layer; and
patterning the buffer material layer and the catalyst material layer to leave a catalyst layer and a buffer layer on the damascene conductive layer.

18. The method of claim 1, wherein the catalyst layer comprises Ni, Fe, Co, Au, Pb, NiFe, CoFe, NiCoFe or a combination thereof.

19. The method of claim 1, wherein the interconnection layer comprises W, Al, TiN, Ti, Cu, Ta or a combination thereof.

20. A method of fabricating an integrated circuit device, the method comprising:
forming a first interlayer dielectric layer on a substrate;
forming a recess in the first interlayer dielectric layer;
forming a conductive layer in the recess;
forming a catalyst layer and a buffer layer on the conductive layer in the recess;
forming a second interlayer dielectric layer on the first interlayer dielectric layer and on the buffer layer;
forming a hole through the second interlayer dielectric layer to expose a portion of the buffer layer;
removing the exposed portion of the exposed buffer layer in the contact hole to expose an underlying portion of the catalyst layer; and
growing carbon nanotubes on the exposed portion of the catalyst layer.

21. The method of claim 20:
wherein forming a hole through the second interlayer dielectric layer to expose a portion of the buffer layer comprises performing a first etching process using the buffer layer as an etching stopper; and
wherein removing the exposed portion of the exposed buffer layer in the contact hole to expose an underlying portion of the catalyst layer comprises performing a second etching process.

22.-27. (canceled)

28. An integrated circuit device comprising:
a substrate;
a stack of layers comprising an interconnection layer on the substrate, a catalyst layer on the interconnection layer and a buffer layer on the catalyst layer;
an interlayer dielectric layer on the buffer layer; and
a carbon nanotube contact extending through the interlayer dielectric layer and the buffer layer to contact the catalyst layer.

29. The integrated circuit device of claim 28, wherein the buffer layer conforms to sidewalls of the catalyst layer and the interconnection layer.

30. The integrated circuit device of claim 28, wherein the buffer layer comprises a nitride layer.

31 The integrated circuit device of claim 28, wherein the buffer layer comprises a conductive material.

32. The integrated circuit device of claim 31, wherein the buffer layer comprises W, Al, TiN, Ti or a combination thereof.

33. (canceled)

34. The integrated circuit device of claim 28, wherein the catalyst layer comprises Ni, Fe, Co, Au, Pb, NiFe, CoFe, NiCoFe or a combination thereof.

35. The integrated circuit device of claim 28, wherein the interconnection layer comprises W, Al, TiN, Ti, Cu, Ta or a combination thereof.
